(19) United States
(12) Patent Application Publication
(10) Pub. No.: US 2006/0115950 A1
(43) Pub. Date: Jun. 1, 2006

(54) Methods of fabricating trench type capacitors including protective layers for electrodes and capacitors so formed

(76) Inventors: Kwang-Bok Kim, Incheon-si (KR); Yong-Sun Ko, Gyeonggi-do (KR); Kyung-Hyun Kim, Seoul (KR)

Correspondence Address: MYERS BIGEL SIBLEY & SAJOVEC, PO BOX 37428, RALEIGH, NC, 27627, US

(21) Appl. No.: 11/284,678

(22) Filed: Nov. 22, 2005

(30) Foreign Application Priority Data
Nov. 26, 2004 (KR) 10-2004-0097792

(51) Int. Cl. H01L 21/20

(52) U.S. Cl. 438/381

(57) ABSTRACT

A method of forming a capacitor can include forming a protective layer on a metal layer in a trench in an insulating layer and outside thereof. A surface of the protective layer and the metal layer beneath can be planarized using a chemical mechanical polishing (CMP) process to expose a surface of the insulating layer outside the trench. Related structures are also disclosed.

### CROSS-REFERENCE TO RELATED APPLICATION

This application claims the benefit of Korean Patent Application No. 10-2004-0097792, filed Nov. 26, 2004, the disclosure of which is hereby incorporated herein by reference in its entirety.

### FIELD OF THE INVENTION

The present invention relates to semiconductor devices and, more particularly, to methods of fabricating capacitors and capacitors so formed.

### BACKGROUND

A semiconductor device can include complicated circuits and interconnection including a plurality of analog elements. With the introduction of such semiconductor devices, multimedia functions have been significantly improved, and thus, high integration and high speed of a semiconductor device have been more easily achieved. Semiconductor devices have also been developed to provide high capacitance capacitors for high speed analog circuits.

A capacitor including a polysilicon/insulator/polysilicon (PIP) structure, includes an upper electrode and a lower electrode composed of conductive polysilicon. If an oxidation reaction occurs at the interface between upper electrode/lower electrode and a dielectric thin film, a native oxide layer may formed, which may decrease the capacitance. Further, the capacitance may also be decreased due to a depletion region formed on a polysilicon layer, which means that the structure may not be appropriate for high speed applications.

Some alternatives to the PIP capacitor structure are metal/insulator/silicon (MIS) or metal/insulator/metal (MIM). MIM type capacitors may have low resistivity and little parasitic capacitance due to depletion. It is also known to form a metal interconnection of a semiconductor device using metal having good conductivity such as aluminum, copper or tungsten, along with MIM structures using similar metals as an electrode. An exemplary MIM type capacitor and methods of fabricating the same are discussed, for example, in U.S. Pat. No. 6,025,226 to Gambino, et. al., and U.S. Pat. No. 6,081,021 entitled “Conductor-Insulator-Conductor structure.”

Hereinafter, a conventional method of fabricating a trench type capacitor is explained in reference to the attached drawings. FIGS. 1a through 1e are sectional views illustrating a conventional method of fabricating a trench type capacitor.

As shown in FIG. 1a, the conventional method of fabricating a trench type capacitor includes forming a first metal layer 22 on a contact plug 12 electrically connected to a semiconductor substrate 10 through a first interlayer insulating layer 14 formed on the semiconductor substrate 10. Further, photoresist (not shown) is deposited on the first metal layer 22, and patterning is performed to maintain the photoresist only on a predetermined region on the contact plug 12. The first metal layer 22 is removed using the photoresist as a mask, and a lower electrode is formed to be electrically connected on the plug. Herein, the first metal layer 22 is formed to have a structure, in which an aluminum layer 16, a titanium layer 18, and a first titanium nitride layer 20 are stacked, to function as a barrier layer for decreasing a resistance with the contact plug 12, and to reduce diffusion of a material in a later formed dielectric layer 28 (FIG. 1d) into the first metal layer 22.

As shown in FIG. 1b, a second interlayer insulating layer 24 is formed with a predetermined thickness on the lower electrode, and photoresist is deposited on the second interlayer insulating layer 24. After the photoresist corresponding to the lower electrode is removed, the second interlayer insulating layer 24 is removed using the photoresist as an etch mask so as to expose the lower electrode, thereby forming a trench 26 selectively exposing the lower electrode through the second interlayer insulating layer 24. Herein, in the case that a step height difference is generated in the second interlayer insulating layer 24 formed on the lower electrode, the second interlayer insulating layer 24 can be planarized using a chemical mechanical polishing (CMP) method, and a trench 26 is formed.

As shown in FIG. 1c, a dielectric layer 28 is formed with a predetermined thickness on the overall surface of the semiconductor substrate 10 having the lower electrode and the second interlayer insulating layer 24 formed thereon.

As shown in FIG. 1d, a second metal layer 34 is formed on the overall surface of the semiconductor substrate 10 having the dielectric layer 28 formed thereon. The second metal layer 34 is formed as a buffer metal layer at the contact surface with the dielectric layer 28 to reduce diffusion of a material in the dielectric layer 28, such as oxygen or nitrogen, and reducing a chemical reaction of the dielectric layer 28, and the second metal layer 34 is formed to have a multiple structure including the second titanium nitride layer 30 and the tungsten layer 32 as a metal layer having good conductivity.

As shown in FIG. 1e, the semiconductor substrate 10 having the second metal layer 34 is planarized using a CMP method to expose the second interlayer insulating layer 24, thereby separating the node of the upper electrode from nodes other adjacent capacitors.

However, in the case that tungsten having a good conductivity and a good corrosion resistance is used as the second metal layer 34, the tungsten layer 32 inside the trench 26 may develop cracks 36 during removing of the tungsten from the second interlayer insulating layer 24 using a CMP method, and planarizing the semiconductor substrate 10 as shown in the drawing, since the tungsten may be sensitive to stress.

Therefore, the conventional method of fabricating a trench type capacitor may have a disadvantage of decreasing a production yield because cracks 36 may be generated on the tungsten layer 32 formed inside the trench 26 in the case that the metal is sensitive to stress is used as the second metal layer 34, and the node separation of the upper electrodes is performed using a CMP process.

### SUMMARY

Embodiments according to the invention can provide methods of fabricating trench type capacitors including protective layers for electrodes and capacitors so formed. Pursuant to these embodiments, a method of forming a capacitor can include forming a protective layer on a metal layer in a trench in an insulating layer and outside thereof. A surface of the protective layer and the metal layer beneath can be planarized using a chemical mechanical polishing (CMP) process to expose a surface of the insulating layer outside the trench.

In some embodiments according to the invention, forming a protective layer is preceded by forming a lower electrode in a trench exposing a conductive region thereunder, forming a dielectric layer on the lower electrode, and forming the metal layer on the dielectric to provide an upper electrode of the capacitor.

In some embodiments according to the invention, forming a protective layer includes forming a silicon oxide layer. In some embodiments according to the invention, forming a silicon oxide layer includes forming the silicon oxide layer to a thickness of about 5000 Å or less. In some embodiments according to the invention, planarizing includes forming an upper electrode of the capacitor by polishing the silicon oxide layer to separate an upper electrode of the capacitor from upper electrodes included in other capacitors formed using the metal layer as a respective upper electrode using silica as slurry and potassium hydroxide (KOH) as an additive.

In some embodiments according to the invention, forming the lower electrode includes sequentially forming an aluminum layer, a titanium layer, and a titanium nitride layer. In some embodiments according to the invention, forming the lower electrode includes forming the aluminum layer and the titanium layer using a vacuum deposition process, a sputtering process, or a chemical vapor deposition process.

In some embodiments according to the invention, forming the lower electrode includes forming the titanium nitride layer to a thickness of about 100 Å to about 1000 Å. In some embodiments according to the invention, forming a dielectric layer includes forming a silicon nitride layer. In some embodiments according to the invention, forming a silicon nitride layer includes forming the silicon nitride layer to a thickness of about 100 Å to about 1500 Å. In some embodiments according to the invention, forming the metal layer includes forming a multi-layered structure including a titanium nitride layer and a tungsten layer.

In some embodiments according to the invention, forming a multi-layered structure includes forming the titanium nitride layer to a thickness of about 50 Å to about 200 Å. In some embodiments according to the invention, forming a multi-layered structure includes forming the tungsten layer to a thickness of about 100 Å to about 1000 Å. In some embodiments according to the invention, the method further includes polishing the tungsten layer by a CMP process using silica as a slurry and hydrogen peroxide (H₂O₂) as an additive.

In some embodiments according to the invention, a trench style capacitor includes a lower electrode of a capacitor in a trench on a contact plug. A dielectric layer is on the lower electrode and an upper electrode of the capacitor is on the dielectric, the upper electrode includes at least a layer of tungsten. A protective layer is on the upper electrode, the protective layer has a planarized upper surface and a thickness of about 5000 Å.

### BRIEF DESCRIPTION OF THE DRAWINGS

FIGS. 1a through 1e are sectional views illustrating a conventional method of fabricating a trench type capacitor; and

FIGS. 2a through 2f are sectional views illustrating fabrication of trench type capacitors in some embodiments according to the present invention.

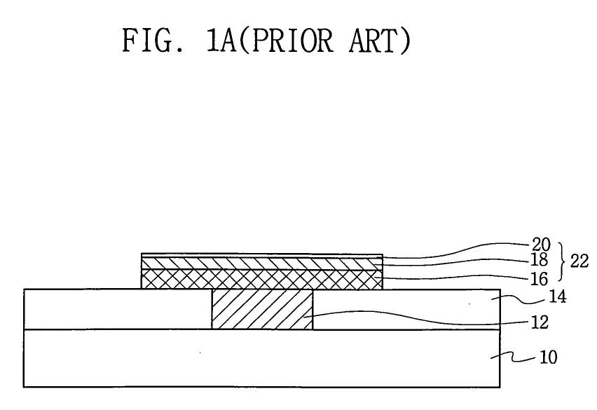

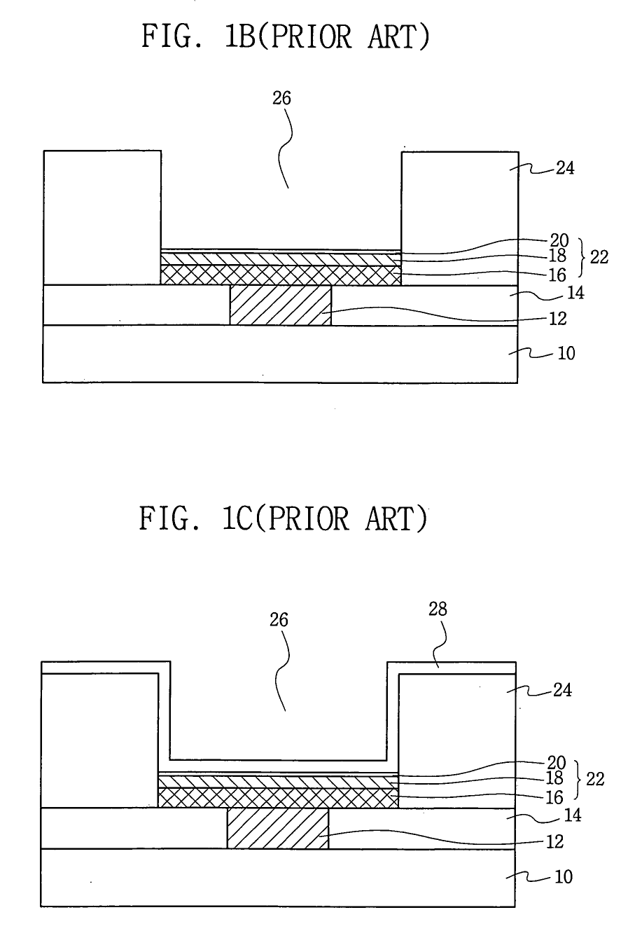

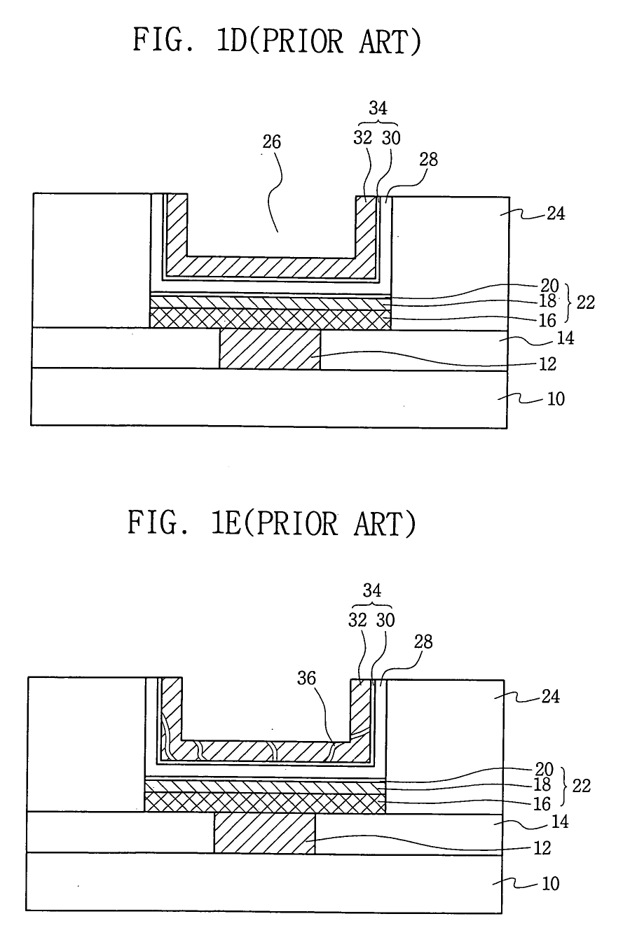

### DESCRIPTION OF EMBODIMENTS ACCORDING TO THE INVENTION

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower”, “bottom”, “upper”, “top”, “beneath”, “above”, and the like are used herein to describe one element's relationship to another elements as illustrated in the Figures. It will be understood that relative terms are intended to encompass different orientations of the subject in the figures in addition to the orientation depicted in the Figures. For example, if the subject in the Figures is turned over, elements described as being on the “lower” side of or “below” other elements would then be oriented on “upper” sides of (or “above”) the other elements. The exemplary term “lower”, can therefore, encompasses both an orientation of “lower” and “upper,” depending of the particular orientation of the figure. Similarly, if the subject in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

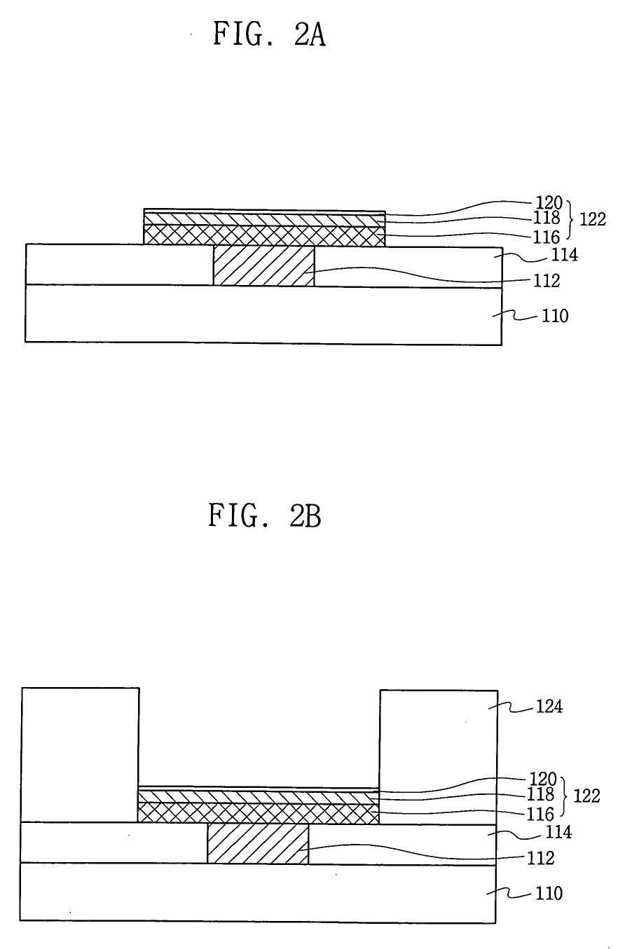

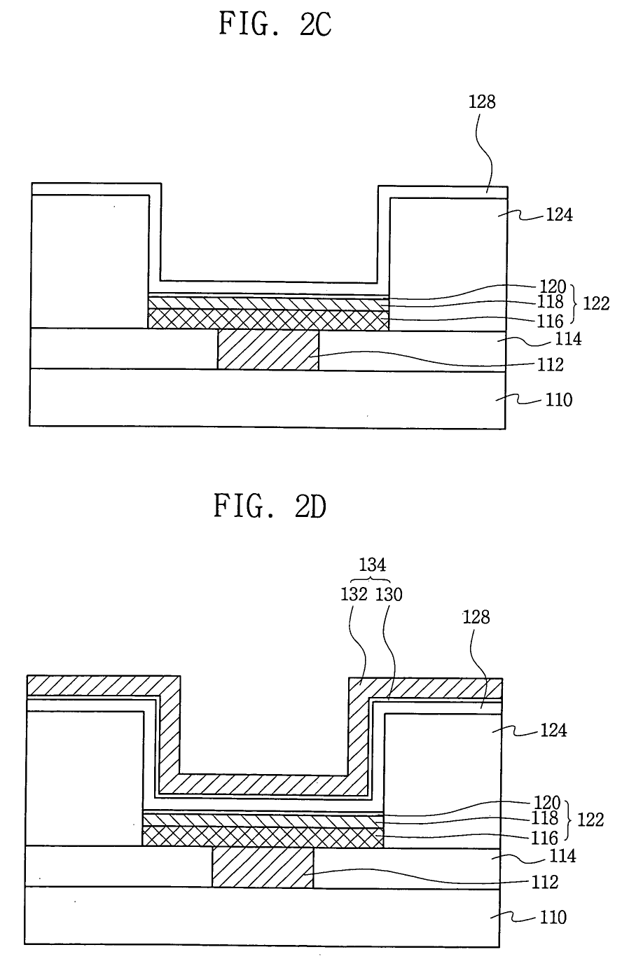

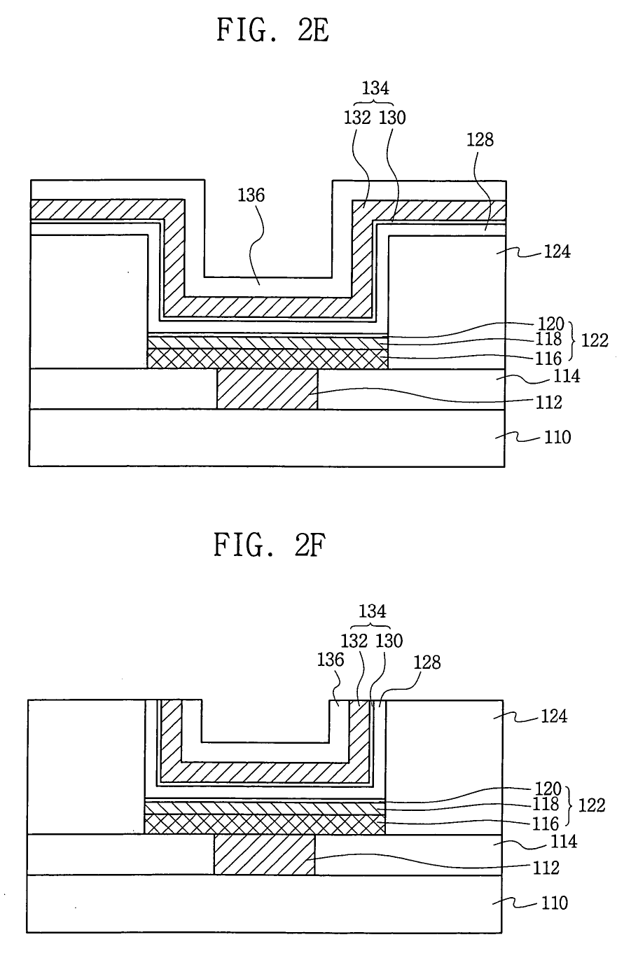

FIGS. 2a through 2f are sectional views illustrating methods of fabricating trench type capacitors in some embodiments according to the present invention. As shown in FIG. 2a, a method of fabricating a trench type capacitor according to the present invention includes forming a first metal layer 122 on a contact plug 112 which is electrically connected to a semiconductor substrate 110 through a first interlayer insulating layer 114 formed on the semiconductor substrate 110. Further, the method includes depositing photoresist on the first metal layer 122, patterning such that the photoresist remains only on a predetermined portion on the contact plug 114, and removing the first metal layer 122 using the photoresist as a mask, thereby forming a lower electrode electrically connected to the upper portion of the plug.

Even though not shown, the contact plug 112 is formed by forming a first contact hole on the first interlayer insulating layer 114 to selectively expose an interconnection or a predetermined conductive region on the first interlayer insulating layer 114 on the semiconductor substrate 110, forming a predetermined metal layer, such as a tungsten layer, to bury the first contact hole, removing the metal layer to expose the first interlayer insulating layer 114, and planarizing the semiconductor substrate 110.

Here, the contact plug 112 may be a metal line insulated by the first interlayer insulating layer 114. Further, before the operation of forming the first metal layer 122, the method may further include removing a native oxide layer formed on the semiconductor substrate 110 or the contact plug 112.

For example, the first metal layer 122 includes an aluminum layer 116 being in contact with the contact plug 112, a titanium layer 118, and a first titanium nitride layer 120, which constitute a multiple layer structure. The aluminum layer 116 has a good conductivity, but may cause a chemical reaction because it is easily corroded by oxygen or nitrogen so as to be changed to aluminum oxide. At this time, the aluminum layer 116 is formed with a thickness of about 2000 Å to 6000 Å, the titanium layer 118 is formed with a thickness of about 50 Å to 200 Å, and the first titanium nitride layer 120 is formed with a thickness of about 100 Å to 1000 Å. Thus, a corrosion-resistant metal layer, such as the titanium layer 118, is formed on the aluminum layer in order to improve a conductivity by a chemical reaction from a dielectric layer 128 (FIG. 2c) to be formed on the first metal layer 122 including the aluminum layer 116 during a subsequent process. Further, a second titanium nitride layer 120 is formed on the titanium layer 118 in order to prevent a chemical reaction due to nitrogen, which may otherwise be diffused from a silicon nitride layer used as the dielectric layer 128 or may be generated from a subsequent annealing process. The aluminum layer 116 and the titanium layer 118 may be formed using a vacuum deposition method, sputtering, or a chemical vapor deposition (CVD) method, and the first titanium nitride layer 120 is formed by a CVD method. In some embodiments according to the invention, a lower electrode of the first metal layer 122 is formed to a length of about 2 μm to 10 μm, and a width of about 1 μm to 5 μm.

As shown in FIG. 2b, a second interlayer insulating layer 124, such as a silicon oxide layer is formed on the lower electrode with a predetermined thickness, and photoresist is deposited on the second interlayer insulating layer 124. After the photoresist formed on the lower electrode is removed, the second interlayer insulating layer 124 is removed to expose the lower electrode, using the photoresist as an etch mask, thereby forming a trench 126. For example, the second interlayer insulating layer 124 is formed with a thickness of about 4000 Å to 8000 Å. Further, the second interlayer insulating layer 124 is formed with a thickness of about 4000 Å to 8000 Å. Further, the trench 126 is formed with the same length and width as those of the lower electrode, or with similar dimensions to those thereof.

Since the second interlayer insulating layer 124 is formed on the lower electrode, the portion of the second interlayer insulating layer 14 thereon may protrude more than other portions of the second interlayer insulating layer 124 formed, for example, beside the lower electrode, to produce a step height difference. If the step height difference of the second interlayer insulating layer 124 is too great, it may cause a patterning failure of the photoresist. Thus, a chemical mechanical polishing (CMP) process for planarizing the second interlayer insulating layer 124 and patterning the photoresist may be further performed in order to planarize the step height difference of the second interlayer insulating layer 124. For example, the CMP process for planarizing the second interlayer insulating layer 124 may be performed, using a slurry such as silica, and additive an such as potassium hydroxide (KOH).

As shown in FIG. 2c, a dielectric layer 128, such as a silicon nitride layer, is formed with a predetermined thickness on the overall surface of the semiconductor substrate 110 having the lower electrode and the second interlayer insulating layer 124 formed thereon. In some embodiments according to the invention, the dielectric layer 128 may be a high-k dielectric material, such as a silicon nitride layer, a high-k aluminum oxide or hafnium oxide.

To reduce the permittivity of the dielectric layer 128, the thickness of the dielectric layer 128 can be reduced. For example, in the case that the dielectric layer 128 is formed of a silicon nitride layer, the dielectric layer 128 may be formed with a thickness of about 100 Å to 1500 Å.

As shown in FIG. 2d, a second metal layer 134 is formed on the overall surface of the semiconductor substrate 110 having the dielectric layer 128 formed thereon. Herein, the second metal layer 134 is composed of a buffer metal layer protecting conductivity of the metal from diffusion of, for example, nitrogen at the contact surface with the dielectric layer 128 and reducing or preventing chemical reaction of the dielectric layer 128, and a conductive metal layer having excellent conductivity, which constitute a multi-layered structure. For example, the second metal layer 134 may be a multi-layered layer structure including a second titanium nitride layer 130 and a tungsten layer 132. The second titanium nitride layer 130 is disposed at the interface with the dielectric layer 128 as described above, and may function as a buffer layer to reduce diffusion of the element causing active chemical reaction, such as nitrogen or oxygen, from the dielectric layer 128 due to a subsequent annealing process or natural reaction, and may be used as a second metal layer 134 inducing charges opposite to the charges charged on the lower electrode. Further, while the tungsten layer 132 may provide corrosion resistance and good conductivity, the tungsten layer 132 can be formed using a vacuum deposition method or a sputtering method and may, if not otherwise addresses, may crack due to stress. For example, the second titanium nitride layer 130 is formed with a thickness of about 50 Å to 200 Å, and the tungsten layer 132 is formed with a thickness of about 100 Å to 1000 Å.

As shown in FIG. 2e, a third interlayer insulating layer 136 such as a silicon oxide layer is formed with a predetermined thickness on the overall surface of the semiconductor substrate 110 having the second metal layer 134 formed thereon. The interlayer insulating layer 136 can form a protective layer to reduce cracks in the tungsten layer 132 due to the stress during the subsequent CMP process of the second metal layer 134. For example, the third interlayer insulating layer 136 is formed with a thickness of about 5000 Å or less.

That is, in the case that the trench type capacitor of the present invention uses an upper electrode composed of metal such as the tungsten layer 132 having a high corrosion resistance, stress may occur due to friction between CMP equipment and the upper electrode during node separation of the upper electrode by a subsequent CMP method. For this reason, the silicon oxide layer is formed as a protective layer on the second metal layer 134 (which is sensitive to stress or impact), such as the tungsten layer 132, in order to reduce cracking of the tungsten layer 132.

If the trench type capacitor is formed to have a small size, the third interlayer insulating layer 136 may be formed with a predetermined thickness enough for the entire trench 126 having the lower electrode formed thereon to be buried. On the contrary, in the case that the trench type capacitor is formed large in size, the trench 126 may not be entirely buried.

As shown in FIG. 2f, the semiconductor substrate 110 having the third interlayer insulating layer 136 formed thereon is planarized to expose the second interlayer insulating layer 124 so as to separate the node of the upper electrode.

Herein, the planarization of the semiconductor substrate 110 may be performed using a CMP process, and thus, the third interlayer insulating layer (i.e., the protective layer) and the second metal layer 134 formed on the second interlayer insulating layer 124 are removed via the CMP process so that the semiconductor substrate 110 is planarized. Further, a portion of the second interlayer insulating layer 124 may be excessively removed during the CMP process. For example, The CMP of the silicon oxide layer used as the third interlayer insulating layer 136 may be performed, using slurry such as silica, and additive such as potassium hydroxide (KOH). The CMP of the tungsten layer 132 used as the second metal layer 134 may be performed using slurry such as silica, and additive such as hydrogen peroxide (H₂O₂).

At this time, since the third interlayer insulating layer 136 formed inside the trench 126 protects the second metal layer 134 during the CMP process sequentially performed on the third interlayer insulating layer 136 and the second metal layer 134 formed on the second interlayer insulating layer 124, and the third interlayer insulating layer 136 is rubbed against the CMP equipment, the stress or impact on the second metal layer 134 can be reduced.

Therefore, in some embodiments according to the invention, a trench type capacitor can be formed by forming the third interlayer insulating layer 136, such as a silicon oxide layer, as a protective layer on the upper electrode composed of the second metal layer 134 (which may be sensitive to stress), such as the tungsten layer 132, thereby reducing cracking of the tungsten layer 132 from the stress caused during the CMP used to separate nodes of the upper electrodes, and thus, increasing or optimizing a production yield.

Even though not shown, a fourth interlayer insulating layer may be formed with a predetermined thickness on the semiconductor substrate 110 having the node of the upper electrode separated. Then, a portion of the fourth interlayer insulating layer formed on the upper electrode is removed, thereby forming a second contact hole exposing the upper electrode. A third metal layer is formed on the fourth interlayer insulating layer having the second contact hole formed therein, and the third metal layer is patterned, thereby forming a metal line electrically connected to the upper electrode.

As described above, in some embodiments according to the present invention, a protective layer, such as a silicon oxide layer, can be formed on the upper electrode including the second metal layer that is sensitive to stress, such as a tungsten layer, to reduce cracking in the tungsten layer during the CMP, thereby increasing a production yield.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed:

1. A method of forming a capacitor comprising:
forming a protective layer on a metal layer in a trench in an insulating layer and outside thereof; and
planarizing a surface of the protective layer and the metal layer beneath using a chemical mechanical polishing (CMP) process to expose a surface of the insulating layer outside the trench.

2. The method according to claim 1 wherein forming a protective layer is preceded by:
forming a lower electrode in a trench exposing a conductive region thereunder;
forming a dielectric layer on the lower electrode; and
forming the metal layer on the dielectric to provide an upper electrode of the capacitor.

3. The method according to claim 1, wherein forming a protective layer comprises forming a silicon oxide layer.

4. The method according to claim 3, wherein forming a silicon oxide layer comprises forming the silicon oxide layer to a thickness of about 5000 Å or less.

5. The method according to claim 3, wherein planarizing comprises forming an upper electrode of the capacitor by polishing the silicon oxide layer to separate an upper electrode of the capacitor from upper electrodes included in other capacitors formed using the metal layer as a respective upper electrode using silica as slurry and potassium hydroxide (KOH) as an additive.

6. The method according to claim 2, wherein forming the lower electrode comprises sequentially forming an aluminum layer, a titanium layer, and a titanium nitride layer.

7. The method according to claim 6, wherein forming the lower electrode comprises forming the aluminum layer and the titanium layer using a vacuum deposition process, a sputtering process, or a chemical vapor deposition process.

8. The method according to claim 6, wherein forming the lower electrode comprises forming the titanium nitride layer to a thickness of about 100 Å to about 1000 Å.

9. The method according to claim 2, wherein forming a dielectric layer comprises forming a silicon nitride layer.

10. The method according to claim 9, wherein forming a silicon nitride layer comprises forming the silicon nitride layer to a thickness of about 100 Å to about 1500 Å.

11. The method according to claim 2, wherein forming the metal layer comprises forming a multi-layered structure including a titanium nitride layer and a tungsten layer.

12. The method according to claim 11, wherein forming a multi-layered structure comprises forming the titanium nitride layer to a thickness of about 50 Å to about 200 Å.

13. The method according to claim 11, wherein forming a multi-layered structure comprises forming the tungsten layer to a thickness of about 100 Å to about 1000 Å.

14. The method according to claim 11, further comprising polishing the tungsten layer by a CMP process using silica as a slurry and hydrogen peroxide (H₂O₂) as an additive.

15. A method of fabricating a trench type capacitor comprising:
forming a contact plug electrically connected to a semiconductor substrate or a conductive region formed on the semiconductor substrate, and a lower electrode with a predetermined size on a first interlayer insulating layer around the contact plug;
forming a second interlayer insulating layer on an overall surface of the semiconductor substrate having the lower electrode formed thereon, and selectively removing the second interlayer insulating layer on the lower electrode, thereby forming a trench exposing the lower electrode;
forming a dielectric layer on an overall surface of the semiconductor substrate having the lower electrode formed thereon;
forming a metal layer on the dielectric layer;
stacking a third interlayer insulating layer protective the metal layer during node separation of an upper electrode using a subsequent CMP process on the metal layer; and
removing the third interlayer insulating layer and the metal layer on the second interlayer insulating layer, using a CMP process to expose the second interlayer insulating layer, and planarizing the semiconductor substrate, thereby separating nodes of an upper electrode.

16. The method according to claim 15, wherein the third interlayer insulating layer is formed of a silicon oxide layer.

17. The method according to claim 16, wherein the silicon oxide layer is polished by a CMP process during node separation of the upper electrode, using silica as slurry and potassium hydroxide (KOH) as additive.

18. The method according to claim 15, wherein the metal layer is formed to have a structure in which a titanium nitride layer and a tungsten layer are stacked.

19. The method according to claim 18, wherein the tungsten layer is polished by a CMP process during node separation of the upper electrode, using silica as slurry and hydrogen peroxide (H₂O₂) as additive.

20. A trench style capacitor comprising:
a lower electrode of the capacitor in a trench on a contact plug;
a dielectric layer on the lower electrode;
an upper electrode of the capacitor on the dielectric, the upper electrode including at least a layer of tungsten; and
a protective layer on the upper electrode, the protective layer having a planarized upper surface and a thickness of about 5000 Å.
